(19) United States
(12) Patent Application Publication
(10) Pub. No.: US 2010/0133540 A1
(43) Pub. Date: Jun. 3, 2010

(54) GLASS SUBSTRATE, DISPLAY DEVICE HAVING THE SAME, AND METHOD OF MANUFACTURING THE DISPLAY DEVICE

(75) Inventors: Se-Ah KWON, Seoul (KR); Min KANG, Seoul (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si, (KR)

(21) Appl. No.: 12/610,566

(22) Filed: Nov. 2, 2009

(30) Foreign Application Priority Data
Dec. 2, 2008 (KR) 10-2008-0121320

(51) Int. Cl. H01L 27/12; C03B 18/00; B32B 3/10

(52) U.S. Cl. 257/59; 65/62; 428/141; 257/E27.111

(57) ABSTRACT

A glass substrate includes at least one surface including an uneven surface having a difference of less than about 0.003 micrometers between a highest point and a lowest point in a section of the glass substrate, the section having a width of about 10 millimeters to about 30 millimeters, and the uneven surfaces being defined by continuously supplying molten glass onto molten metal and cooling the molten glass which floats on the molten metal.

This application claims priority to Korean Patent Application No. 10-2008-0121320 filed on Dec. 2, 2008, and all the benefits accruing therefrom under 35 U.S.C. §119, the disclosure of which is incorporated herein by reference in its entirety.

### BACKGROUND OF THE INVENTION

1. Field of the Invention

The present invention relates to a glass substrate, a display device having the same, and a method of manufacturing the display device, and more particularly, to a glass substrate which is structured not to cause stains on a screen of a display device even when manufactured without a grinding process, a display device having the glass substrate, and a method of manufacturing the display device.

2. Description of the Related Art

As modern society becomes more dependent on sophisticated information and communication technology, the market needs for larger and thinner displays are growing. In particular, since conventional cathode ray tubes (“CRTs”) have failed to fully satisfy these market needs, the demand for flat panel displays (“FPDs”), such as plasma display panels (“PDPs”), plasma address liquid crystal display panels (“PALCs”), liquid crystal displays (“LCDs”), and organic light emitting diodes (“OLEDs”), is exploding.

Of FPDs, an LCD includes a lower substrate having an array of TFTs, an upper substrate facing the lower substrate, and a liquid crystal layer interposed between the lower and upper substrates. The LCD displays images by controlling the intensity of an electric field applied to the liquid crystal layer. An LCD includes a display panel having an upper substrate and a lower substrate. Since a display panel is non-self-luminous, it requires light sources to provide light thereto in order to display images. The display panel displays images by controlling the transmittance of light received from the light sources.

An upper substrate and a lower substrate use glass substrates as their base substrates. When a surface of a glass substrate is not ground uniformly, stains may be formed on a screen of an LCD. Thus, the surface of the glass substrate should be ground uniformly. However, the addition of the process of grinding a surface of a glass substrate may complicate the entire manufacturing process and significantly increase costs. This has led to a demand for a structure which can reduce or effectively prevent the formation of stains on a screen of a display panel even when a surface of a glass substrate is not ground.

### BRIEF SUMMARY OF THE INVENTION

An exemplary embodiment of the present invention provides a glass substrate which is structured not to cause stains on a screen of a display device even when manufactured without a grinding process.

An exemplary embodiment of the present invention also provides a display device including a glass substrate which is structured not to cause stains on a screen of the display device even when manufactured without a grinding process.

An exemplary embodiment of the present invention also provides a method of manufacturing a display device including a glass substrate which is structured not to cause stains on a screen of the display device even when manufactured without a grinding process.

In an exemplary embodiment of the present invention, there is provided a glass substrate which is manufactured by continuously supplying molten glass onto molten metal and cooling the molten glass which floats on the molten metal, the glass substrate including at least one surface of which is an uneven surface having a difference of less than about 0.003 micrometers (μm) between a highest point and a lowest point in a section with a width of about 10 millimeters (mm) to about 30 millimeters (mm).

In an exemplary embodiment of the present invention, there is provided a display device including an upper substrate, and a lower substrate which faces the upper substrate and includes a thin-film transistor (“TFT”). At least one of the upper substrate and the lower substrate includes a glass substrate which is manufactured by continuously supplying molten glass onto molten metal and cooling the molten glass which floats on the molten metal. At least one surface of the glass substrate is an uneven surface having a difference of less than about 0.003 μm between a highest point and a lowest point in a section with a width of about 10 mm to about 30 mm.

In an exemplary embodiment of the present invention, there is provided a method of manufacturing a display device. The method includes forming a glass substrate including at least one surface which is an uneven surface having a difference of less than about 0.003 μm between a highest point and a lowest point in a section with a width of about 10 mm to about 30 mm, and forming at least one of an upper substrate and a lower substrate, which faces the upper substrate and comprises a TFT, by using the glass substrate.

### BRIEF DESCRIPTION OF THE DRAWINGS

The above and other aspects and features of the present invention will become more apparent by describing in detail exemplary embodiments thereof with reference to the attached drawings, in which:

FIG. 1 is a flowchart illustrating an exemplary embodiment of a method of manufacturing a display device according to the present invention;

FIG. 2 schematically illustrates an exemplary embodiment of a process of manufacturing a glass substrate according to the present invention;

FIG. 3 is a schematic cross-sectional view of an exemplary embodiment of a float bath shown in FIG. 2;

FIG. 4 is a plan view of the float bath shown in FIG. 3;

FIG. 5 is a perspective view of an exemplary embodiment of a first glass substrate according to the present invention;

FIG. 6 is a cross-sectional view of the first glass substrate taken along line A-A′ of FIG. 5;

FIG. 7A is an enlarged cross-sectional view of a region B of the first glass substrate shown in FIG. 6;

FIG. 7B illustrates an exemplary embodiment of an uneven surface of a glass substrate to explain a method of calculating a highest point and a lowest point of the uneven surface;

FIG. 8 is a cross-sectional view of an exemplary embodiment of a lower substrate included in the display device according to the present invention;

FIG. 9 is a cross-sectional view of an exemplary embodiment of a display device according to the present invention;

FIG. 10 is a cross-sectional view of another exemplary embodiment of a display device according to the present invention; and

FIG. 11 is a cross-sectional view of another exemplary embodiment of a display device according to the present invention.

### DETAILED DESCRIPTION OF THE INVENTION

Advantages and features of the present invention and methods of accomplishing the same may be understood more readily by reference to the following detailed description of exemplary embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will be defined by the appended claims. In the drawings, the size and relative sizes of layers and regions may be exaggerated for clarity. Like reference numerals refer to like elements throughout the specification.

It will be understood that when an element or layer is referred to as being “on” or “connected to” another element or layer, the element or layer can be directly on or connected to another element or layer or intervening elements or layers. In contrast, when an element is referred to as being “directly on” or “directly connected to” another element or layer, there are no intervening elements or layers present. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “lower,” “upper,” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

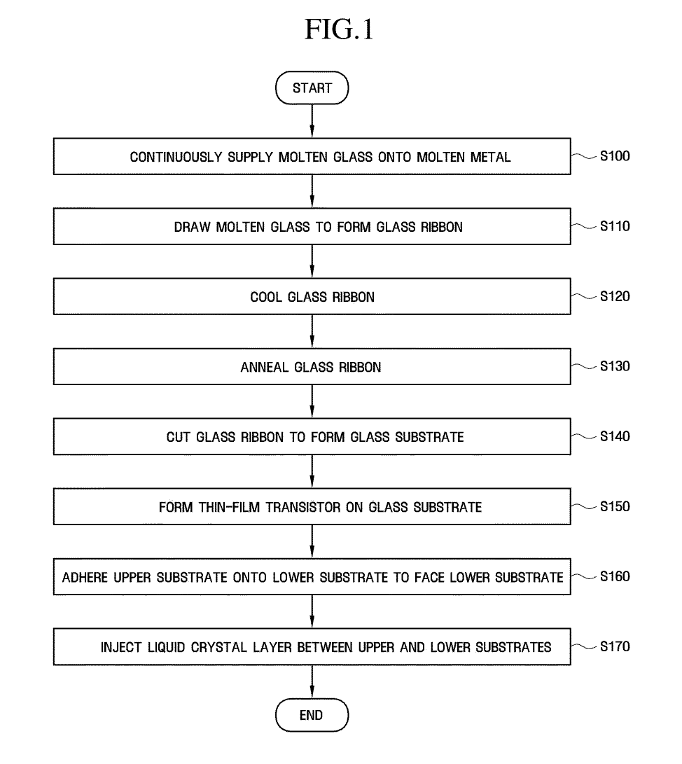

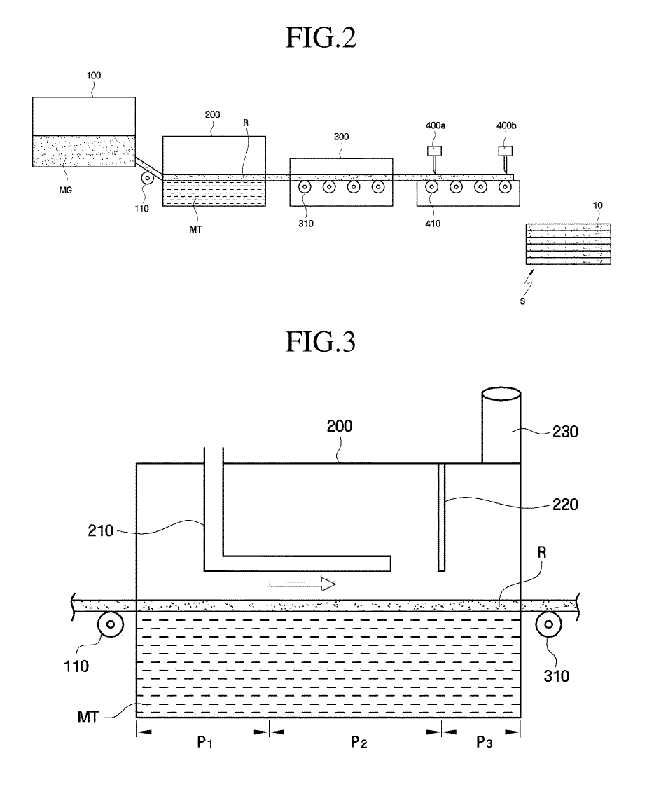

Hereinafter, an exemplary embodiment of a method of manufacturing a display device 1 according to the present invention will be described in detail with reference to FIGS. 1 through 9. FIG. 1 is a flowchart illustrating the method of manufacturing the display device 1 according to the present invention. FIG. 2 schematically illustrates an exemplary embodiment of a process of manufacturing a glass substrate according to an embodiment of the present invention.

The display device 1 (see FIG. 9) may include a glass substrate which is manufactured by a floating method and without a grinding process. The process of manufacturing a glass substrate included in the display device 1 will first be described below.

Referring to FIGS. 1 and 2, molten glass MG is continuously supplied onto molten metal MT (operation S100). Specifically, raw materials of a first glass substrate 10 (see FIG. 5) are injected into a smelting furnace 100. In an exemplary embodiment, the raw materials may include glass cullet mixed with soda lime, silica, sodium carbonate, limestone, dolomite, feldspar, and sodium sulfate. The smelting furnace 100 should be heated to such a high temperature that the raw materials of the first glass substrate 10 are dissolved to form the homogenized, molten glass MG. In one exemplary embodiment, the smelting surface 100 may be heated to approximately 1500° C. or above. After the molten glass MG is dissolved and has bubbles removed therefrom, the molten glass MG is supplied to a float bath 200.

As the molten glass MG flows out of the smelting furnace 100, it may be cooled to a predetermined temperature. In one exemplary embodiment, the molten glass MG may be cooled to approximately a range of about 1100° C. to 1300° C., and supplied accordingly to the float bath 200. While the molten glass MG may be cooled, the molten glass MG may be maintained at a temperature higher than a temperature at which it structurally eases. The molten glass MG is supplied to the float bath 200 by a first roller 110.

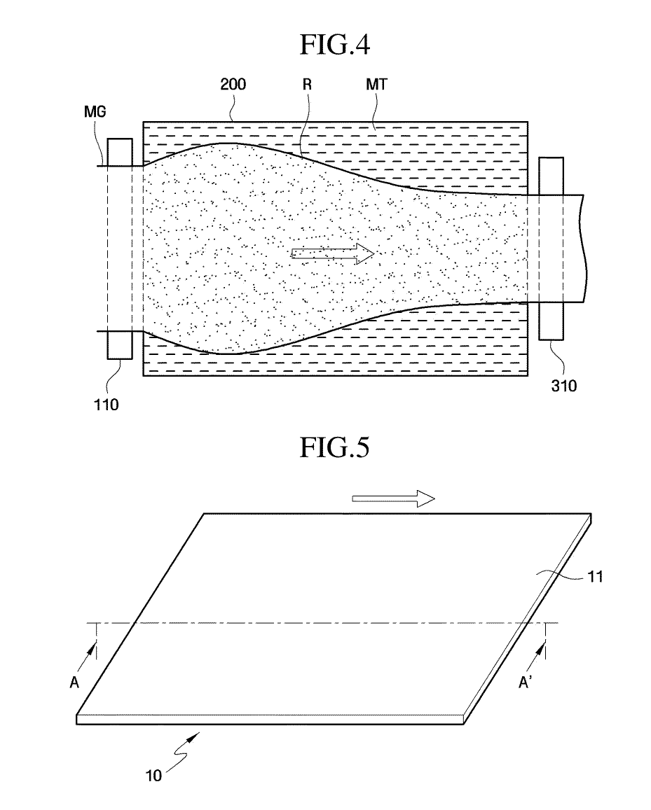

FIG. 3 is a schematic cross-sectional view of the float bath 200 shown in FIG. 2. FIG. 4 is a plan view of the float bath 200 shown in FIG. 3.

Referring to FIGS. 1 and 3, the molten glass MG is drawn to form a glass ribbon R (operation S110).

The molten glass MG supplied to the float bath 200 essentially floats on a surface of the molten metal MT. As the molten glass MG is continuously supplied to the float bath 200, it forms a continuous ribbon R of glass substantially in the shape of a thin plate. The molten glass MG is drawn, and thus kept in the shape of a thin plate having a substantially fixed thickness.

The float bath 200, in which the molten glass MG is transformed into the glass ribbon R, is filled with the molten metal MT. The molten glass MG moves through the float bath 200 while floating on the molten metal MT. The molten glass MG is drawn while disposed on the molten metal MT, and thus transformed into the glass ribbon R with a substantially uniform thickness.

A bottom portion of the glass ribbon R is shaped substantially like a flat glass plate by the molten metal MT, and a top portion thereof is kept substantially flat (e.g., planar) by air. In an exemplary embodiment, the molten metal MT filling the float bath 200 may be molten tin.

The inside of the float bath 200 may be divided into a heating section P₁, a molding section P₂, and a cooling section P₃. The heating section P₁, the molding section P₂, and the cooling section P₃ are disposed continuous with each other within the float bath 200. The glass ribbon R passes through the heating section P₁, the molding section P₂, and the cooling section P₃ sequentially, and then exits from the float bath 200.

The glass ribbon R is heated by a heater 210 in the heating section P₁. As the glass ribbon R is heated by a heater 210, the glass ribbon R may be drawn to a substantially uniform thickness. The glass ribbon R which passed completely through the heating section P₁ in the direction of the arrow shown in FIG. 3, enters the molding section P₂. In the molding section P₂, the glass ribbon R may be fire-polished, such as a surface of the ribbon glass R being polished with fire.

The glass ribbon R which passed completely through the molding section P₂ in the direction of the arrow shown in FIG. 3, enters the cooling section P₃. The fire-polished glass ribbon R passes completely through the cooling section P₃ in the direction of the arrow shown in FIG. 3. The glass ribbon R is cooled in the cooling section P₃ (operation S120). As the glass ribbon R cools, it gradually hardens. In one exemplary embodiment, when the first glass substrate 10 is manufactured using soda lime glass, the temperature of the molten metal MT may be approximately 1050° C. at an inlet of the float bath 200 through which the molten glass MG enters the float bath 200, and may be approximately 600° C. at an outlet of the float bath 200 through which the molten glass MG exits the float bath 200. Since a glass transition point of soda lime glass is 550° C., the glass ribbon R moves in the float bath 200 while maintaining a relative liquid state, such that even as the molten glass MG may be cooled, the molten glass MG may be maintained at a temperature higher than a temperature at which it structurally eases.

In the cooling section P₃, a reducing atmosphere is created to prevent oxidation of the glass ribbon R. A partition 220 may be disposed in the float bath 200 to separate the space in which the heater 210 is installed from the cooling section P₃. A gas controller 230 may supply a gas, which includes nitrogen gas (N₂) and hydrogen gas (H₂), in the cooling section P₃.

Referring to FIG. 4, the molten glass MG is fed into the float bath 200 in the direction of the arrow shown in FIG. 4, and shaped into the glass ribbon R. As the glass ribbon R goes through a drawing process, a width of the glass ribbon R is increased and then controlled to a desired width. Through this process, the thickness of the glass ribbon R may be controlled to be substantially uniform. The temperature of the molten metal MT which fills the float bath 200, and the cooling and moving speeds of the glass ribbon R affect the surface morphology of the glass ribbon R such that the temperature and the cooling and moving speeds of the glass ribbon R should be controlled to obtain desired surface quality. The uneven surface having desired surface quality and characteristics maybe defined solely by the continuous supplying molten glass onto molten metal, the drawing of the process of the glass ribbon and the cooling the molten glass which floats on the molten metal, such that the uneven surface is formed without a grinding process.

Referring back to FIGS. 1 and 2, once leaving the float bath 200, the glass ribbon R is annealed (operation S130). The glass ribbon R which passed completely through the float bath 200 is supplied to an annealing lehr 300. The annealing lehr 300 gradually cools the glass ribbon R, thereby stabilizing the glass structure of the glass ribbon R.

The glass ribbon R which passed through the annealing lehr 300 is not further transformed and substantially maintains the plate shape and the surface characteristics from the forming in the float bath 200. The glass ribbon R in the annealing lehr 300 gradually cools at least above an annealing point. As used herein, the annealing point denotes a highest temperature at which internal thermal stress can be relieved without deforming a product.

The annealing lehr 300 includes a second roller 310 for moving the glass ribbon R. The second roller 310 slowly moves the glass ribbon R by considering the cooling speed of the glass ribbon R.

The glass ribbon R is cut to form the first glass substrate 10 (operation S140).

The glass ribbon R which passed completely through the annealing lehr 300 is moved by a third roller 410 which forwards the glass ribbon R to a cutting process. The glass ribbon R is cut by cutters 400a and 400b to form the first glass substrate 10 of an appropriate size. The cutters 400a and 400b may include diamond tips for cutting glass. A plurality of the first glass substrate 10 manufactured as described above, may be stacked to a desired height to form a glass stack S, and the glass stack S is moved to subsequent manufacturing processes and/or stations.

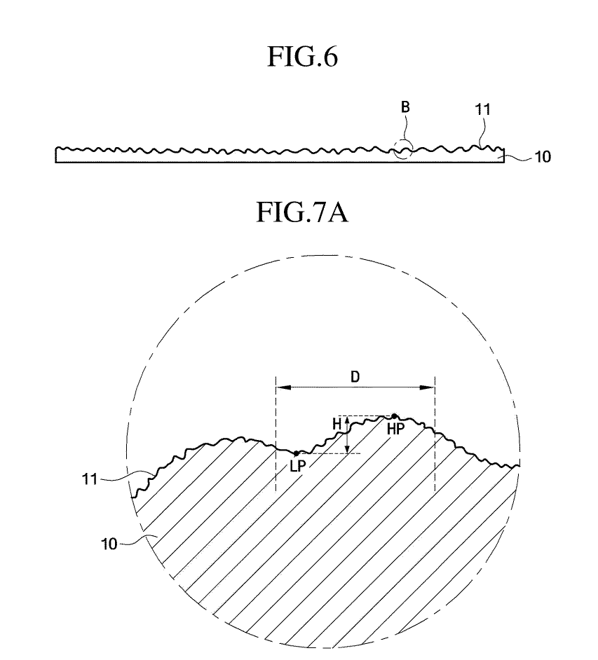

The first glass substrate 10 will now be described in detail with reference to FIGS. 5 and 6. FIG. 5 is a perspective view of an exemplary embodiment of the first glass substrate 10 according to the present invention. FIG. 6 is a cross-sectional view of the first glass substrate 10 taken along line A-A′ of FIG. 5.

Referring to FIGS. 5 and 6, at least one surface of the first glass substrate 10 may be an uneven surface 11. In an exemplary embodiment, the first glass substrate 10 may be a soda-lime glass substrate, a boro-silicate glass substrate, a silicate glass substrate, a lead glass substrate, or the like. The uneven surface 11 denotes a substantially flat and planar surface of the first glass substrate 10, which includes minute height differences. While a non-ground surface of the first glass substrate 10 is flat, minute height differences may exist in the non-ground surface. As used in the present specification, the uneven surface 11 denotes a non-ground surface. The uneven surface 11 may be any one of a surface of the first glass substrate 10 which contacts the molten metal MT in the float bath 200 and a surface of the first glass substrate 10 which contacts air in the float bath 200.

In an exemplary embodiment, the uneven surface 11 may be any one of an upper surface of the first glass substrate 10 or a lower surface of the glass substrate 10, as shown in FIG. 6. However, the present invention is not limited thereto, and the uneven surface 11 may also be each of both the lower and the upper surfaces of the first glass substrate 10 illustrated in FIG. 6.

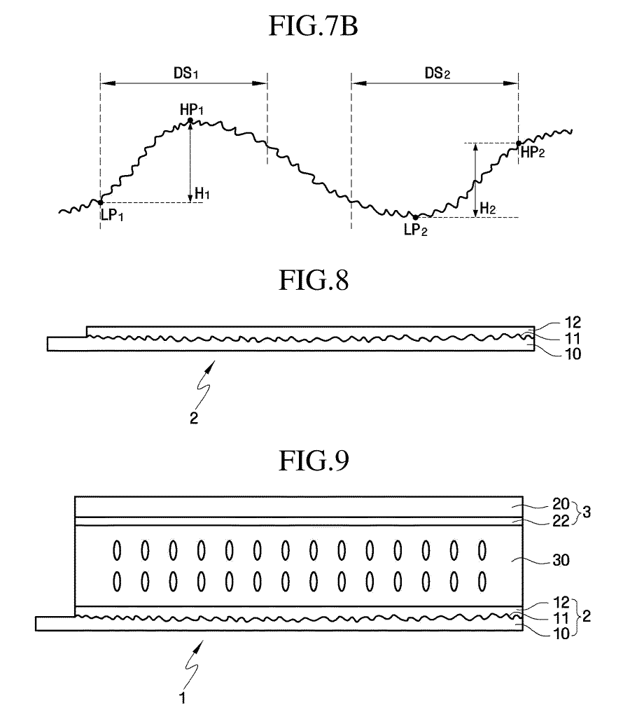

The surface morphology of the first glass substrate 10 used in the display device 1 will now be described in detail with reference to FIGS. 7A and 7B. FIG. 7A is an enlarged cross-sectional view of a region B of the first glass substrate 10 shown in FIG. 6. FIG. 7B illustrates an exemplary embodiment of an uneven surface of a glass substrate to explain a method of calculating a highest point and a lowest point of the uneven surface.

The uneven surface 11 may be formed in a predetermined direction of the first glass substrate 10. A wave-shaped uneven surface 11 may be formed in the same direction as the direction in which the first glass substrate 10 moves while being manufactured. The uneven surface 11 may be formed while the glass ribbon R floats on the molten metal MT in the float bath 200. The shape of the first glass substrate 10 may vary according to the moving speed and cooling temperature of the glass ribbon R through the manufacturing processes.

The uneven surface 11 may include a series of regular and/or irregular shapes. The uneven surface 11 must satisfy certain conditions to enable the first glass substrate 10 to be used in the display device 1 without going through a grinding process.

Referring to FIG. 7A, an enlarged version of the uneven surface 11 shows a series of waveforms having various amplitudes. A difference H between a highest point HP and a lowest point LP in a section D of the uneven surface 11, is critical to display quality of a display panel. A distance defined by H is taken in a direction substantially perpendicular to a plane of the first glass substrate 10, and a distanced defined by the section D is taken in a direction substantially parallel to the plane of the first glass substrate 10.

In the illustrated embodiment, the section D is a section arbitrarily selected to have a width of about 10 millimeters (mm) to about 30 millimeters (mm). As used herein, the section D is an arbitrarily selected section of the uneven surface 11. The section D may be defined in the same direction as the direction in which molten glass moves through apparatus of a manufacturing process. When the difference H between the highest point HP and the lowest point LP is less than about 0.003 micrometers (μm), screen flickering resulting from interference does not occur even when the first glass substrate 10 is used in the display device 1 without going through the grinding process. That is, a difference H between the highest point HP and the lowest point LP being less than about 0.003 μm, is considered a critical value of a surface characteristic of the first glass substrate 10, such that the manufactured first glass substrate 10 satisfies a certain condition to enable the first glass substrate 10 to be used in the display device 1 without going through a grinding process.

Referring to FIG. 7B, to calculate a highest point and a lowest point of an uneven surface, the uneven surface may be divided into a first section DS₁ and a second section DS₂. Each of the first section DS₁ and the second section DS₂ may have a width taken in the direction substantially parallel to the plane of the first glass substrate 10 of about 10 mm to about 30 mm. The first section DS₁ and the second section DS₂ may be separated from each other as illustrated in FIG. 7, or may overlap each other.

Referring to the first section DS₁, a highest point HP₁ and a lowest point LP₁ in the first section DS₁ can be measured. A difference H₁ between the highest point HP₁ and the lowest point LP₁ should be less than about 0.003 μm, such that the manufactured first glass substrate 10 meets the critical value of the surface characteristic to satisfy the certain condition discussed above and enables the first glass substrate 10 to be used in the display device 1 without going through a grinding process.

Referring to the second section DS₂, a difference H₂ between a highest point HP₂ and a lowest point LP₂ in the second section DS₂ should be less than about 0.003 μm, such that the manufactured first glass substrate 10 meets the critical value of the surface characteristic to satisfy the certain condition discussed above and enables the first glass substrate 10 to be used in the display device 1 without going through a grinding process. In a section, which has a width of about 10 mm to about 30 mm, of the uneven surface 11 of the first glass substrate 10, a difference between a highest point and a lowest point must always be less than about 0.003 μm, which represents a substantially uniform surface without grinding the first glass substrate 10, so that no stains are formed on the screen of the display device 1. Each section taken on the uneven surface 11 of the first glass substrate 10 should be less than about 0.003 μm. Advantageously, when the first substrate 10 includes the substantially uniform surface without grinding the first glass substrate 10, a manufacturing process (e.g., grinding) can be omitted and manufacturing costs can be reduced.

A glass substrate including an uneven surface having a difference of less than about 0.003 μm between a highest point and a lowest point in a section with a width of about 10 mm to about 30 mm is formed by continuously supplying molten glass onto molten metal and cooling the molten glass which floats on the molten metal during a manufacturing process. The uneven surface of the glass substrate having a difference of less than about 0.003 μm between a highest point and a lowest point in a section with a width of about 10 mm to about 30 mm, is considered a structural characteristic of the final glass substrate, and of a final display device employing the glass substrate. Since the uneven surface of the glass structure having a difference of less than about 0.003 μm between a highest point and a lowest point in a section with a width of about 10 mm to about 30 mm is imparted solely by an operation of continuously supplying molten glass onto molten metal and cooling the molten glass which floats on the molten metal during the manufacturing process, such operation is considered to impart the distinct structural characteristic of the uneven surface of the glass structure having a difference of less than about 0.003 μm between a highest point and a lowest point in a section with a width of about 10 mm to about 30 mm.

FIG. 8 is a cross-sectional view of an exemplary embodiment of a lower substrate 2 included in the display device 1 according to the present invention.

Referring to FIGS. 1 and 8, thin-film transistors (“TFTs”) and various devices are disposed on the first glass substrate 10 (operation S150). FIG. 8 is a cross-sectional view of an exemplary embodiment of the lower substrate 2 included in the display device 1 according to the present invention.

The lower substrate 2 includes a TFT array 12 disposed on the first glass substrate 10. The TFT array 12 includes gate lines and data lines which are arranged substantially in a matrix. In an exemplary embodiment, the gate lines and data lines arranged substantially in a matrix may define a plurality of a pixel region. A pixel region may be defined as an independent area unit capable of independent controlling liquid crystal. In each pixel region, a pixel electrode and a TFT functioning as a switching device, which applies a data voltage to the pixel electrode, are disposed. The TFT array 12 may be disposed on the uneven surface 11 of the first glass substrate 10. After the TFT array 12 is disposed on the uneven surface 11 of the first glass substrate 10, if a liquid crystal layer 30 (see FIG. 9) is injected in a subsequent process during manufacturing of the display device 1, the effect of the uneven surface 11 on image quality is reduced.

FIG. 9 is a cross-sectional view of the display device 1 according to the present invention. Referring to FIGS. 1 and 9, an upper substrate 3 is combined with the lower substrate 10 and disposed to face the lower substrate 10 (operation S160).

The upper substrate 3 includes a second glass substrate 20 and a common electrode 22 disposed on the second glass substrate 20. The common electrode 22 and the pixel electrode (not shown) of the lower substrate 2 form an electric field. The upper substrate 3 faces the lower substrate 2. The liquid crystal layer 30 is injected between the upper substrate 3 and the lower substrate 2 to complete the display device 1 (operation S170).

The uneven surface 11 of the first glass substrate 10 may be disposed adjacent to and facing the liquid crystal layer 30. When the uneven surface 11 is disposed adjacent to and facing the TFT array 12 and the liquid crystal layer 30, the formation of stains on the screen can be significantly reduced.

An electric field formed between the upper substrate 3 and the lower substrate 2 rotates liquid crystal molecules of the liquid crystal layer 30, thereby controlling light transmittance of the display device 1. Consequently, images are displayed on the display device 1.

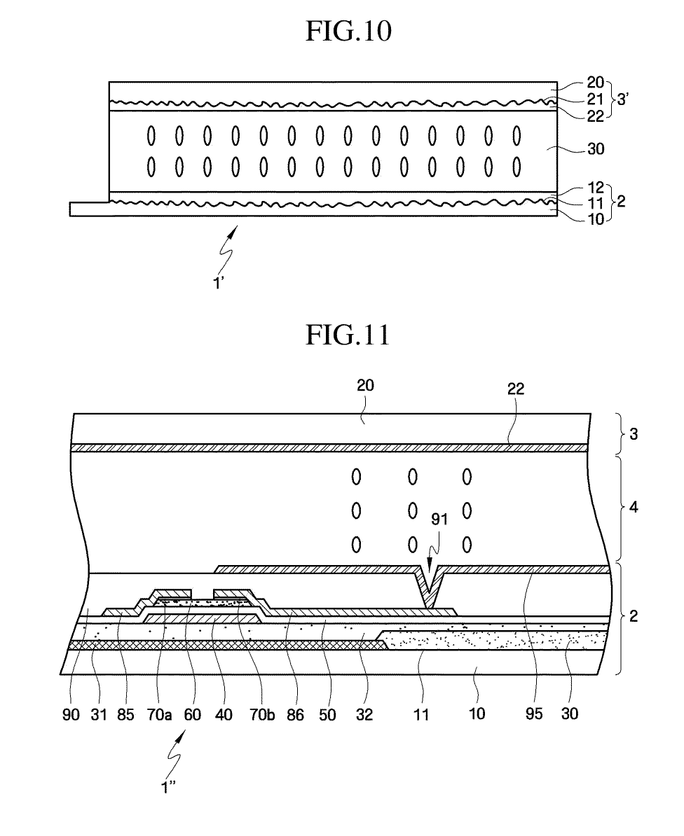

Hereinafter, a display device 1′ according to another exemplary embodiment of the present invention will be described in detail with reference to FIG. 10. FIG. 10 is a cross-sectional view of the display device 1′ according to another exemplary embodiment of the present invention. For simplicity, elements substantially identical to those of the display device 1 of FIG. 9 are indicated by like reference numerals, and thus their description will be omitted.

In the display device 1′, at least one surface of a second glass substrate 20 of an upper substrate 3′ is an uneven surface 21. The uneven surface 21 of the second glass substrate 20 has a difference of less than about 0.003 μm between a highest point and a lowest point in a section with a width of about 10 mm to about 30 mm, such that the manufactured second glass substrate 20 meets the critical value of the surface characteristic to satisfy the certain condition discussed above and enables the second glass substrate 20 to be used in the display device 1 without going through a grinding process.

The second glass substrate 20 may be manufactured using the same method as that for the first glass substrate 10 according to the illustrated embodiment described above. An uneven surface 11 of a first glass substrate 10 may be disposed to face the uneven surface 21 of the second glass substrate 20. When the uneven surface 11 of the first glass substrate 10 is installed to face the uneven surface 21 of the second glass substrate 20, and when a liquid crystal layer 30 is injected between them, the formation of stains on images displayed on the display device 1′ can be reduced or effectively prevented.

Hereinafter, a display device 1″ according to another exemplary embodiment of the present invention will be described in detail with reference to FIG. 11. FIG. 11 is a cross-sectional view of the display device 1″ according to the present invention.

The display device 1″ according to the illustrated embodiment includes a color filter on array (“COA”) structure in which a color filter 30 and a TFT array are sequentially disposed on a first glass substrate 10. At least one surface of the first glass substrate 10 is an uneven surface 11. The uneven surface 11 has a difference of less than about 0.003 μm between a highest point and a lowest point in a section with a width of about 10 mm to about 30 mm, such that the manufactured first glass substrate 10 meets the critical value of the surface characteristic to satisfy the certain condition discussed above and enables the first glass substrate 10 to be used in the display device 1 without going through a grinding process.

In the COA structure, all elements excluding a common electrode 22 are disposed on a lower substrate 2. In this structure, even when the first glass substrate 10 is a non-ground glass substrate, the formation of stains resulting from light interference can be reduced or effectively prevented. The COA structure is not the only structure which reduces or prevents the formation of stains on the display device 1″. In an alternative embodiment, the display device 1″ may also include an array on color filter (“AOC”) structure.

Referring to FIG. 11, a black matrix 31 is disposed on the first glass substrate 10, which may be made of non-ground soda lime glass. In the illustrated embodiment, the black matrix 11 may define a pixel region, and a plurality of the pixel region may be disposed on the lower substrate 2. The black matrix 31 functions as a light-shielding film which reduces or effectively prevents leakage of light to regions other than pixel regions.

The color filter 30 is disposed in each pixel region between the black matrices 31, in a layout view of the display device 1″. The color filter 30 is overlapped by a pixel electrode 95, which is disposed in each pixel region. In each pixel region, the red, green and/or blue color filter 30 may be disposed. An overcoat layer 32 for planarization may be disposed on the black matrix 31 and the color filter 30. The overcoat layer 32 may be disposed substantially on an entire of the first glass substrate 10.

A gate electrode 40 is disposed on the overcoat layer 32. The gate electrode 40 may overlap a portion of the black matrix 31. The gate electrode 40 is coated with a gate insulating film 50 which may be disposed substantially on a whole of the first glass substrate 10.

A pair of semiconductor layers 60 are disposed on the gate insulating film 30, and may include hydrogenated amorphous silicon or polycrystalline silicon. Ohmic contact layers 70a and 70b, such as including silicide or n+ hydrogenated amorphous silicon doped with n-type impurities in high concentration, are disposed on the semiconductor layers 60, respectively. The ohmic contact layers 70a and 70b form a pair and disposed respectively on the semiconductor layers 60.

A source electrode 85 and a drain electrode 86 are disposed on the ohmic contact layers 70a and 70b and the gate insulating film 50. The source electrode 85 and the drain electrode 86 are disposed separated from each other with respect to the gate electrode 40

The gate electrode 40, the source electrode 85, and the drain electrode 86 form three terminals of a TFT. The TFT functions as a switching device which controls a pixel electrode 95. The TFT may overlap a portion of the black matrix 31.

A passivation layer 90 including an insulating layer is disposed on the source electrode 85, the drain electrode 86, and exposed portions of the semiconductor layers 60.

A contact hole 91 is disposed extending completely through the passivation layer 90 to electrically connect the drain electrode 86 to the pixel electrode 95.

The pixel electrode 95 is disposed in each pixel region and may include a transparent conductor material, such as indium tin oxide (“ITO”) or indium zinc oxide (“IZO”), or a reflective conductor such as aluminum.

An upper substrate 3 faces the lower substrate 2, and a liquid crystal layer 4 is interposed between the upper substrate 3 and the lower substrate 2. The upper substrate includes the common electrode 22. The common electrode 22 may be disposed on a second glass substrate 20.

While the present invention has been particularly shown and described with reference to exemplary embodiments thereof, it will be understood by those of ordinary skill in the art that various changes in form and detail may be made therein without departing from the spirit and scope of the present invention as defined by the following claims. The exemplary embodiments should be considered in a descriptive sense only and not for purposes of limitation.

What is claimed is:

1. A glass substrate comprising:
an uneven surface having a distance in a first direction of less than about 0.003 micrometers between a highest point and a lowest point in a section of the glass substrate, the section having a width in a second direction substantially perpendicular to the first direction of about 10 millimeters to about 30 millimeters,
wherein the uneven surface of the glass substrate is defined by continuously supplying molten glass onto molten metal and cooling the molten glass which floats on the molten metal.

2. The glass substrate of claim 1, wherein the section of the glass substrate is defined in a same direction as a direction in which the molten glass moves.

3. The glass substrate of claim 2, wherein the molten glass comprises soda lime.

4. The glass substrate of claim 1, wherein the molten glass comprises soda lime.

5. A display device comprising:
an upper substrate; and
a lower substrate which faces the upper substrate and comprises a thin-film transistor,
wherein at least one of the upper substrate and the lower substrate comprises a glass substrate including at least one surface which is an uneven surface having a distance of less than about 0.003 micrometers between a highest point and a lowest point in a section of the respective substrate, the section having a width of about 10 millimeters to about 30 millimeters, and the uneven surface being defined by continuously supplying molten glass onto molten metal and cooling the molten glass which floats on the molten metal.

6. The display device of claim 5, wherein the section of the respective substrate is defined in a same direction as a direction in which the molten glass moves.

7. The display device of claim 6, wherein the molten glass comprises soda lime.

8. The display device of claim 7, wherein the thin film transistor is disposed on the uneven surface.

9. The display device of claim 6, wherein the thin film transistor is disposed on the uneven surface.

10. The display device of claim 6, wherein the uneven surface is disposed on at least one of facing surfaces of the upper substrate and the lower substrate.

11. The display device of claim 10, wherein the molten glass comprises soda lime.

12. The display device of claim 11, wherein the thin film transistor is disposed on the uneven surface.

13. The display device of claim 10, wherein the thin film transistor is disposed on the uneven surface.

14. A method of manufacturing a display device, the method comprising:
forming a glass substrate including at least one surface which is an uneven surface having a difference of less than about 0.003 micrometers between a highest point and a lowest point in a section of the glass substrate, the section having a width of about 10 millimeters to about 30 millimeters; and
forming at least one of an upper substrate, and a lower substrate which faces the upper substrate and comprises a thin film transistor, by using the glass substrate.

15. The method of claim 14, wherein the forming a glass substrate comprises continuously supplying molten glass onto molten metal and cooling the molten glass which floats on the molten metal.

16. The method of claim 15, wherein the section of the glass substrate is defined in a same direction as a direction in which the molten glass moves.

17. The method of claim 16, wherein the molten glass comprises soda lime.

18. The method of claim 17, wherein the thin film transistor is formed on the uneven surface.

19. The method of claim 18, wherein the forming a glass substrate including at least one surface which is an uneven surface, does not include a grinding process.

20. The method of claim 14, wherein the section of the glass substrate is defined in a same direction as a direction in which the molten glass moves.

21. The method of claim 20, wherein the molten glass comprises soda lime.

22. The method of claim 21, wherein the thin film transistor is formed on the uneven surface.

23. The method of claim 22, wherein the forming a glass substrate including at least one surface which is an uneven surface, does not include a grinding process.

24. The method of claim 20, wherein the thin film transistor is formed on the uneven surface.

25. The method of claim 24, wherein the forming a glass substrate including at least one surface which is an uneven surface, does not include a grinding process.
